(19) United States
(12) Patent Application Publication
(10) Pub. No.: US 2025/0116632 A1
(43) Pub. Date: Apr. 10, 2025

(54) ULTRASONIC DETECTION OF VOIDS AND CRACKS IN SUBSTRATES

(71) Applicant: Orbotech Ltd., Yavne (IL)

(72) Inventors: Yuri Paskover, Binyamina (IL); Tal Goichman, Kiryat Ono (IL); Mor Azarya, Merhavia Moshav (IL); Itay Peled, Jerusalem (IL)

(21) Appl. No.: 18/679,610

(22) Filed: May 31, 2024

Related U.S. Application Data
(60) Provisional application No. 63/612,346, filed on Dec. 19, 2023.
(60) Provisional application No. 63/542,343, filed on Oct. 4, 2023.

(51) Int. Cl. G01N 29/04; G01N 29/07; G01N 29/265; H01L 21/66

(52) U.S. Cl. CPC G01N 29/043; G01N 29/07; G01N 29/265; H01L 22/12; G01N 2291/044

(57) ABSTRACT

A method of ultrasonic detection of voids and cracks in substrates includes controlling an ultrasonic transducer to generate an acoustic signal applied to the substrate, receiving a reflected acoustic signal detected by an ultrasonic detector, and determining a defect in the substrate based on phase and intensity of the reflected acoustic signal compared to the acoustic signal applied to the substrate.

### CROSS-REFERENCE TO RELATED APPLICATIONS

This application claims priority to the provisional patent application filed Oct. 4, 2023, and assigned U.S. App. No. 63/542,343, and the provisional patent application filed Dec. 19, 2023, and assigned U.S. App. No. 63/612,346, the entire disclosures of which are hereby incorporated by reference.

### FIELD OF THE DISCLOSURE

This disclosure relates to inspection systems and, more particularly, to inspection systems for detecting defects in semiconductor substrates.

### BACKGROUND OF THE DISCLOSURE

Evolution of the electronics manufacturing industry is placing greater demands on yield management and, in particular, on metrology and inspection systems. Critical dimensions continue to shrink, yet the industry needs to decrease time for achieving high-yield, high-value production. Minimizing the total time from detecting a yield problem to fixing it maximizes the return-on-investment for an electronics manufacturer.

Inspection processes are used at various steps during electronics manufacturing to detect defects on wafers, electronic devices, or electrical circuits to promote higher yield in the manufacturing process and, thus, higher profits. Inspection has always been an important part of fabricating electronic devices such as integrated circuits (ICs), flat panel displays (e.g., organic light emitting diode on silicon (OLEDoS) display panels), and printed circuit boards (PCBs), including assembled PCBs. However, as feature dimensions decrease, inspection becomes even more important to the successful manufacture of acceptable electronic devices because smaller defects can cause devices and assemblies to fail. For instance, as feature dimensions decrease, detection of defects of decreasing size has become necessary because even relatively small defects may cause unwanted aberrations in the devices.

Many inspection processes rely on optical detection systems to identify defects. However, optical detection of defects can be difficult or impossible when the material is diffusive or non-transparent or is comprised of several layers.

Therefore, what is needed is a method for detecting defects in various types of substrates to improve production yield.

### BRIEF SUMMARY OF THE DISCLOSURE

An embodiment of the present disclosure provides a method. The method may comprise attaching an ultrasonic transducer to a substrate; attaching an ultrasonic detector to the substrate; controlling, with a processor, the ultrasonic transducer to generate an acoustic signal applied to the substrate; receiving, with the processor, a reflected acoustic signal detected by the ultrasonic detector; and determining, with the processor, a defect in the substrate based on phase and intensity of the reflected acoustic signal compared to the acoustic signal applied to the substrate.

In some embodiments, the substrate may comprise silicon, glass, ceramic, or organic materials, and the defect may be a void or crack in the substrate.

In some embodiments, the substrate may comprise a printed circuit board. The ultrasonic transducer may be attached to a metal line of the printed circuit board, and the ultrasonic detector may be attached to the metal line. The defect may be a crack in the metal line or a void between repaired segments of the metal line.

In some embodiments, the ultrasonic detector may be attached to the substrate distal from the ultrasonic transducer.

In some embodiments, the ultrasonic detector may be attached to the substrate at the same position as the ultrasonic transducer.

In some embodiments, the method may further comprise controlling, with the processor, the ultrasonic transducer to generate an acoustic signal applied to the defect in the substrate to repair the defect.

In some embodiments, the method may further comprise depositing solder material to the defect in the substrate to repair the defect.

Another embodiment of the present disclosure provides a method. The method may comprise: attaching a multi-segment ultrasonic transducer to a chip, wherein the chip is disposed on a substrate with underfill material disposed therebetween; attaching an ultrasonic detector to the chip; controlling, with a processor, the multi-segment ultrasonic transducer to generate an acoustic signal from each segment applied to the chip, wherein the acoustic signal from each segment of the multi-segment ultrasonic transducer has a phase delay; receiving, with the processor, a reflected acoustic signal detected by the ultrasonic detector; and determining, with the processor, a defect in the underfill material based on phase and intensity of the reflected acoustic signal.

In some embodiments, the phase delay of the acoustic signal from each segment of the multi-segment ultrasonic transducer may focus an acoustic wave at different depths relative to the chip, such that the acoustic wave may be reflected by the underfill material and detected by the ultrasonic detector.

In some embodiments, the method may further comprise controlling, with the processor, the multi-segment ultrasonic transducer to generate an acoustic signal from at least one segment applied to the defect in the underfill material to repair the defect. The acoustic signal applied to the defect may be configured to melt or sinter the underfill material to repair the defect.

Another embodiment of the present disclosure provides a method. The method may comprise: positioning an ultrasonic transducer proximal to a first side of a substrate; controlling, with a processor, the ultrasonic transducer to generate an acoustic signal applied to the substrate; scanning, with a laser source, a laser beam across a second side of the substrate, wherein the first side is opposite to the second side; detecting, with a detector, a reflected laser beam, wherein the reflected laser beam is a reflection of the laser beam from the second side of the substrate; and determining, with the processor, a defect in the substrate based on phase and amplitude variations in the reflected laser beam received from the detector.

In some embodiments, the method may further comprise controlling, with the processor, the ultrasonic transducer to generate an acoustic signal applied to the defect in the substrate to repair the defect.

In some embodiments, before controlling, with the processor, the ultrasonic transducer to generate an acoustic signal applied to the defect in the substrate to repair the defect, the method may further comprise scanning the substrate relative to the ultrasonic transducer to position the ultrasonic transducer proximal to the defect in the substrate.

Another embodiment of the present disclosure provides a method. The method may comprise: positioning an ultrasonic transducer and an ultrasonic detector proximal to a substrate; controlling, with a processor, the ultrasonic transducer to emit an acoustic wave toward the substrate, wherein the acoustic wave is reflected by the substrate and received by the ultrasonic detector; scanning the substrate relative to the ultrasonic transducer and the ultrasonic detector; and determining, with the processor, a defect in the substrate based on a change in phase or intensity of the reflected acoustic wave detected by the ultrasonic detector as the substrate is scanned.

In some embodiments, the substrate may be a solid-state battery, and the defect may be a crack or dendrite in the solid-state battery.

In some embodiments, the method may further comprise controlling, with the processor, the ultrasonic transducer to emit an acoustic wave applied to the defect in the substrate to repair the defect.

In some embodiments, before controlling, with the processor, the ultrasonic transducer to emit an acoustic wave applied to the defect in the substrate to repair the defect, the method may further comprise scanning the substrate relative to the ultrasonic transducer to position the ultrasonic transducer proximal to the defect in the substrate.

### DESCRIPTION OF THE DRAWINGS

For a fuller understanding of the nature and objects of the disclosure, reference should be made to the following detailed description taken in conjunction with the accompanying drawings, in which:

FIG. 1A is a flowchart of a detection method according to an embodiment of the present disclosure;

FIG. 1B is a diagram of a system utilizing the method of FIG. 1A;

FIG. 1C is a diagram of another system utilizing the method of FIG. 1A;

FIG. 2A is a flowchart of a detection method according to another embodiment of the present disclosure;

FIG. 2B is a diagram of a system utilizing the method of FIG. 2A;

FIG. 3A is a flowchart of a detection method according to another embodiment of the present disclosure;

FIG. 3B is a diagram of a system utilizing the method of FIG. 3A;

FIG. 4A is a flowchart of a detection method according to another embodiment of the present disclosure;

FIG. 4B is a diagram of a system utilizing the method of FIG. 4A;

FIGS. 5A and 5B illustrate a repair process of an embodiment of the present disclosure;

FIGS. 6A and 6B illustrate a repair process of another embodiment of the present disclosure; and

FIGS. 7A to 7C illustrate a repair process of another embodiment of the present disclosure.

### DETAILED DESCRIPTION OF THE DISCLOSURE

Although claimed subject matter will be described in terms of certain embodiments, other embodiments, including embodiments that do not provide all of the benefits and features set forth herein, are also within the scope of this disclosure. Various structural, logical, process step, and electronic changes may be made without departing from the scope of the disclosure. Accordingly, the scope of the disclosure is defined only by reference to the appended claims.

Embodiments of the present disclosure relate to the detection of defects in a substrate 101 using ultrasound. Such substrates 101 may include a semiconductor wafer, substrate (made of silicon, glass, ceramic, or organic materials), printed circuit board (comprising metal lines made of copper or other conductive materials), solid-state batteries, or other materials/devices. Systems 100 of the embodiments of the present disclosure may comprise an ultrasonic transducer 110, and ultrasonic detector 120, and a processor 130. In general, the processor 130 may be configured to control the ultrasonic transducer 110 to generate an acoustic signal applied to the substrate 101, and the ultrasonic detector 120 may detect a reflected acoustic signal from the substrate 101. The processor 130 may be configured to receive the reflected acoustic signal from the substrate 101 and determine that there is a defect 102 in the substrate 101 based on phase and intensity of the reflected acoustic signal compared to the acoustic signal applied to the substrate 101.

The processor 130 may include a microprocessor, a microcontroller, or other devices. The processor 130 may be coupled to the components of the system 100 in any suitable manner (e.g., via one or more transmission media, which may include wired and/or wireless transmission media) such that the processor 130 can receive output. The processor 130 may be configured to perform a number of functions using the output. An inspection tool can receive instructions or other information from the processor 130. The processor 130 optionally may be in electronic communication with another inspection tool, a metrology tool, a repair tool, or a review tool (not illustrated) to receive additional information or send instructions.

The processor 130 may be part of various systems, including a personal computer system, image computer, mainframe computer system, workstation, network appliance, internet appliance, or other device. The subsystem(s) or system(s) may also include any suitable processor known in the art, such as a parallel processor. In addition, the subsystem(s) or system(s) may include a platform with high-speed processing and software, either as a standalone or a networked tool.

The processor 130 may be disposed in or otherwise part of the system 100 or another device. In an example, the processor 130 may be part of a standalone control unit or in a centralized quality control unit. Multiple processors 130 may be used, defining multiple subsystems of the system 100.

The processor 130 may be implemented in practice by any combination of hardware, software, and firmware. Also, its functions as described herein may be performed by one unit, or divided up among different components, each of which may be implemented in turn by any combination of hardware, software and firmware. Program code or instructions for the processor 130 to implement various methods and functions may be stored in readable storage media, such as a memory.

If the system 100 includes more than one subsystem, then the different processors 130 may be coupled to each other such that images, data, information, instructions, etc. can be sent between the subsystems. For example, one subsystem may be coupled to additional subsystem(s) by any suitable transmission media, which may include any suitable wired and/or wireless transmission media known in the art. Two or more of such subsystems may also be effectively coupled by a shared computer-readable storage medium (not shown).

The processor 130 may be configured to perform a number of functions using the output of the system 100 or other output. For instance, the processor 130 may be configured to send the output to an electronic data storage unit or another storage medium. The processor 130 may be further configured as described herein.

The processor 130 may be configured according to any of the embodiments described herein. The processor 130 also may be configured to perform other functions or additional steps using the output of the system 100 or using images or data from other sources.

The processor 130 may be communicatively coupled to any of the various components or sub-systems of system 100 in any manner known in the art. Moreover, the processor 130 may be configured to receive and/or acquire data or information from other systems (e.g., inspection results from an inspection system such as a review tool, a remote database including design data and the like) by a transmission medium that may include wired and/or wireless portions. In this manner, the transmission medium may serve as a data link between the processor 160 and other subsystems of the system 100 or systems external to system 100. Various steps, functions, and/or operations of system 100 and the methods disclosed herein are carried out by one or more of the following: electronic circuits, logic gates, multiplexers, programmable logic devices, ASICs, analog or digital controls/switches, microcontrollers, or computing systems. Program instructions implementing methods such as those described herein may be transmitted over or stored on carrier medium. The carrier medium may include a storage medium such as a read-only memory, a random-access memory, a magnetic or optical disk, a non-volatile memory, a solid-state memory, a magnetic tape, and the like. A carrier medium may include a transmission medium such as a wire, cable, or wireless transmission link. For instance, the various steps described throughout the present disclosure may be carried out by a single processor 130 (or computer subsystem) or, alternatively, multiple processors 130 (or multiple computer subsystems). Moreover, different sub-systems of the system 100 may include one or more computing or logic systems. Therefore, the above description should not be interpreted as a limitation on the present disclosure but merely an illustration.

Ultrasonic sensitivity to defects can be estimated by partial reflection intensity on the interface between the defect and medium. The interface reflectivity may be dictated by the acoustic impedance of the two media:

$$\frac{{I}_{ref}}{{I}_{inc}} = \frac{{( {Z}_{1} - {Z}_{2} )}^{2}}{{( {Z}_{1} + {Z}_{2} )}^{2}} ,$$

where I_{ref} and I_{inc} are the intensities of the reflected and incident acoustic signals respectively, and Z₁ and Z₂ are acoustic impedance of the two media forming the interface. The acoustic impedance may be determined by: Z=cⱼ×pⱼ, where c is the sound velocity in the medium and p is the density of the material. For example:

$${c}_{Cu - Bulk} ≅ 5000 m / s , {ρ}_{Cu} = 8.9 \times {10}^{3} \frac{kg}{{m}^{3}} ⇒ {Z}_{cu} = 4.45 \times {10}^{6} \frac{kg}{{m}^{2} s}$$

$${c}_{si} = 8433 m / s {ρ}_{Si} = 2.33 \times {10}^{3} \frac{kg}{{m}^{3}} ⇒ {Z}_{Si} = 1.97 \times {10}^{6} \frac{kg}{{m}^{2} s}$$

Resolution may be proportional to the wavelength of the soundwave

$$λ = \frac{{c}_{material}}{{v}_{sound}} .$$

For example, λ_{cu}≈2.5 μm and λₛᵢ≈4.2 μm. Sensitivity (i.e., detectability of a void) may be proportional to the reflected wave intensity and may be minimally dependent on the material:

$${I}_{ref} = {I}_{inc} \frac{{( {Z}_{1} - {Z}_{2} )}^{2}}{{( {Z}_{1} + {Z}_{2} )}^{2}} = \frac{{Z}_{1}^{2} - 2 {Z}_{1} {Z}_{2} + {Z}_{2}^{2}}{{( {Z}_{1} + {Z}_{2} )}^{2}} {≅}_{{Z}_{2} ≪ {Z}_{1 ∼ air}} 1 - 2 \frac{{Z}_{2}}{{Z}_{1}} ≅ 1$$

almost for any material Z₁.

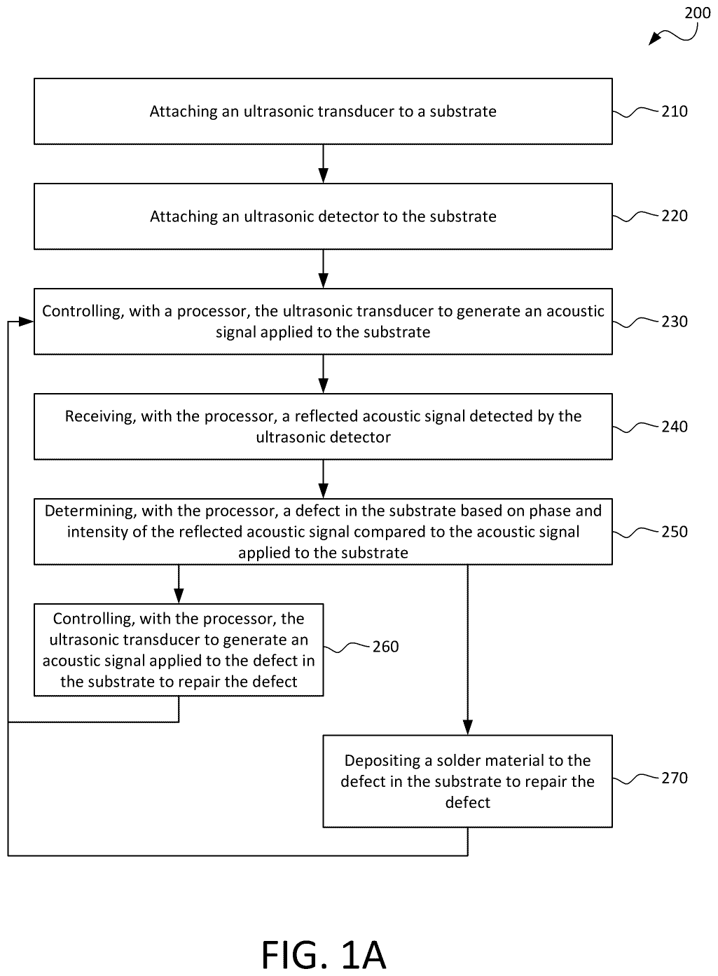

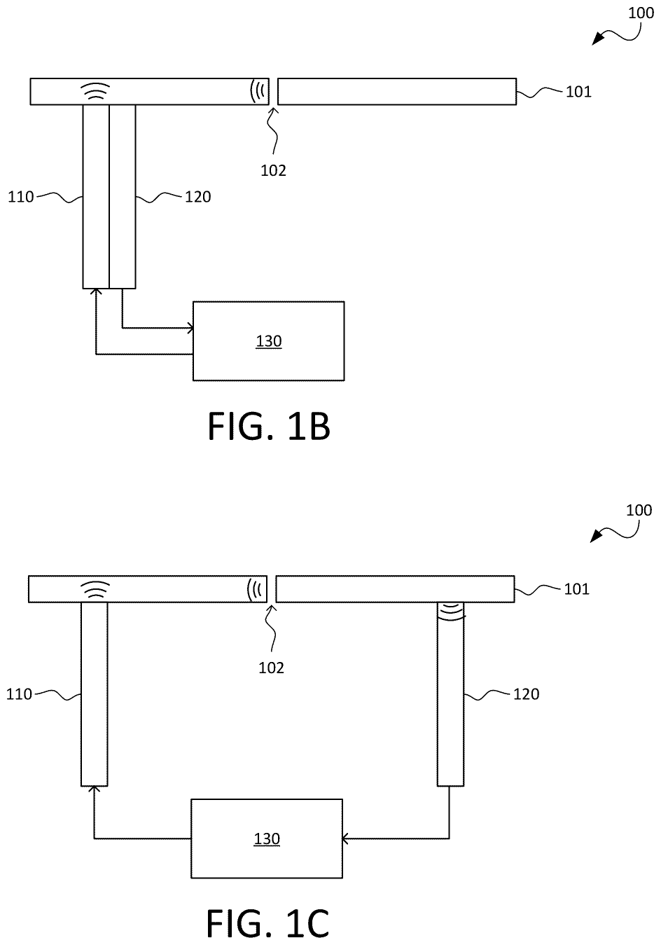

An embodiment of the present disclosure provides a method 200, shown in FIG. 1A. Systems 100 used in connection with the method 200 are shown in FIGS. 1B and 1C. The method 200 may comprise the following steps.

At step 210, an ultrasonic transducer is attached to a substrate. In some embodiments, the substrate may comprise silicon, glass, ceramic, or organic materials. The ultrasonic transducer may be directly attached to the substrate. In other embodiments, the substrate may be a printed circuit board including a metal line (e.g., made of copper or other conductive materials). The ultrasonic transducer may be attached to a metal line of the printed circuit board. In some embodiments, the ultrasonic transducer may be indirectly attached to the substrate, e.g., with a mediator disposed therebetween. The mediator may be a liquid, gel, or other material having a similar impedance to the substrate.

At step 220, an ultrasonic detector is attached to the substrate. In some embodiments, the ultrasonic detector may be attached to the substrate distal from the ultrasonic transducer (as shown in FIG. 1C). In other embodiments, the ultrasonic detector may be attached to the substrate at the same position as the ultrasonic transducer (as shown in FIG. 1B). In some embodiments, the ultrasonic detector may be indirectly attached to the substrate, e.g., with a mediator disposed therebetween. The mediator may be a liquid, gel, or other material having a similar impedance to the substrate. In some embodiments the ultrasonic transducer may also function as an ultrasonic detector, based on careful time control between acoustic signal generation and detection.

At step 230, a processor controls the ultrasonic transducer to generate an acoustic signal applied to the substrate. The acoustic signal may have a frequency in the range of 10 s of MHz or up to several GHz. Since the ultrasonic transducer is attached to the substrate, the acoustic signal generated by the ultrasonic transducer may travel through the substrate and may be reflected by the substrate.

At step 240, the processor receives a reflected acoustic signal detected by the ultrasonic detector. Since the ultrasonic detector is attached to the substrate, the acoustic signal travelling through the substrate or reflected by the substrate may be detected by the ultrasonic detector.

At step 250, the processor determines a defect in the substrate based on phase and intensity of the reflected acoustic signal compared to the acoustic signal applied to the substrate. For example, a defect present in the substrate may cause the intensity of the acoustic signal to change (e.g., increased intensity in the arrangement shown in FIG. 1B and reduced intensity in the arrangement shown in FIG. 1C) and/or may cause a phase shift in the acoustic signal. Thus, by comparing the acoustic signal applied to the substrate by the ultrasonic transducer to the reflected acoustic signal detected by the ultrasonic detector, defects in the substrate can be identified. Such defects may include voids or cracks in the substrate, cracks in a metal line of a PCB, or voids between repaired segments of a metal line of a PCB.

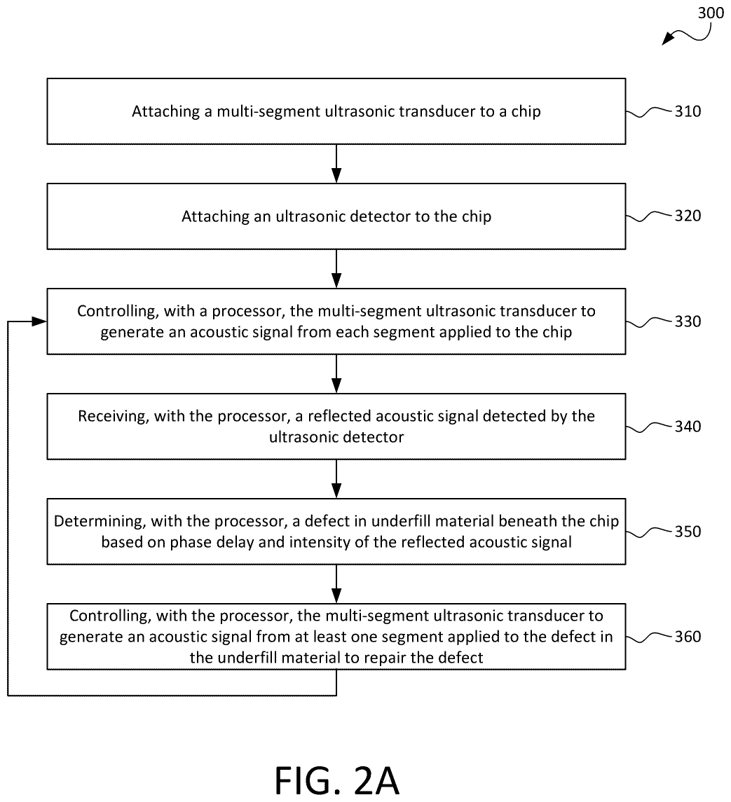

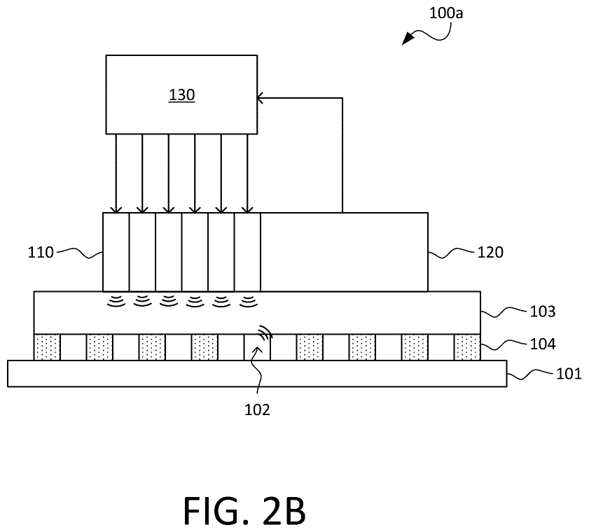

Another embodiment of the present disclosure provides a method 300, as shown in FIG. 2A. A system 100a used in connection with the method 300 is shown in FIG. 2B. The system 100a differs from the system 100 in that the ultrasonic transducer 110 is a multi-segment ultrasonic transducer, in which each segment is configured to emit an acoustic signal. In addition, the system 100a is applied to a chip 103 disposed on the substrate 101, and an underfill material 104 may be disposed between the chip 103 and the substrate 101. The method 300 may comprise the following steps.

At step 310, a multi-segment ultrasonic transducer is attached to a chip. The chip may be disposed on a substrate with underfill material disposed therebetween. In some embodiments, the multi-segment ultrasonic transducer may be indirectly attached to the chip, e.g., with a mediator disposed therebetween. The mediator may be a liquid, gel, or other material having a similar impedance to the chip.

At step 320, an ultrasonic detector is attached to the chip. In some embodiments, the ultrasonic detector may be attached to the chip distal from the multi-segment ultrasonic transducer. In other embodiments, the ultrasonic detector may be attached to the chip at the same position as the multi-segment ultrasonic transducer. In some embodiments, the ultrasonic detector may be integrated with the multi-segment ultrasonic transducer as a single device. In some embodiments, the ultrasonic detector may be indirectly attached to the chip, e.g., with a mediator disposed therebetween. The mediator may be a liquid, gel, or other material having a similar impedance to the chip. In some embodiments, some or all of the segments of the multi-segment ultrasonic transducer may also function as an ultrasonic detector, based on careful time control between acoustic signal generation and detection.

At step 330, a processor controls the multi-segment ultrasonic transducer to generate an acoustic signal from each segment applied to the chip. The acoustic signal may have a frequency in the range of 10 s of MHz or up to several GHz. The processor may be configured to control each segment of the multi-segment ultrasonic transducer individually, which can allow for focusing of the acoustic signal to a particular part of the chip by controlling a particular segment or group of segments and can allow scanning of the acoustic signal by sequentially controlling one or more segments across the chip. Since the multi-segment ultrasonic transducer is attached to the chip, the acoustic signal generated by the multi-segment ultrasonic transducer may travel through the chip, the underfill material, and the substrate, and may be reflected by the chip, the underfill material, and the substrate. The acoustic signal from each segment of the multi-segment ultrasonic transducer may have a phase delay between segments. The phase delay of the acoustic signal from each segment of the multi-segment ultrasonic transducer may focus the acoustic wave at different depths relative to the chip.

At step 340, the processor receives a reflected acoustic signal detected by the ultrasonic detector. Since the ultrasonic detector is attached to the chip, the acoustic signal travelling through the chip or reflected by the chip, the underfill material, or the substrate may be detected by the ultrasonic detector.

At step 350, the processor determines a defect in the underfill material based on phase delay and intensity of the reflected acoustic signal. For example, a defect/void in the underfill material may cause the intensity of the acoustic signal to be increase and/or may cause a phase shift in the acoustic signal due to a high impedance difference between the underfill material and air. The phase shift of the reflected acoustic signal may correspond to a particular segment of the multi-segment ultrasonic transducer. Thus, by comparing the acoustic signal applied to the chip by the multi-segment ultrasonic transducer to the reflected acoustic signal detected by the ultrasonic detector, defects in the underfill material can be identified.

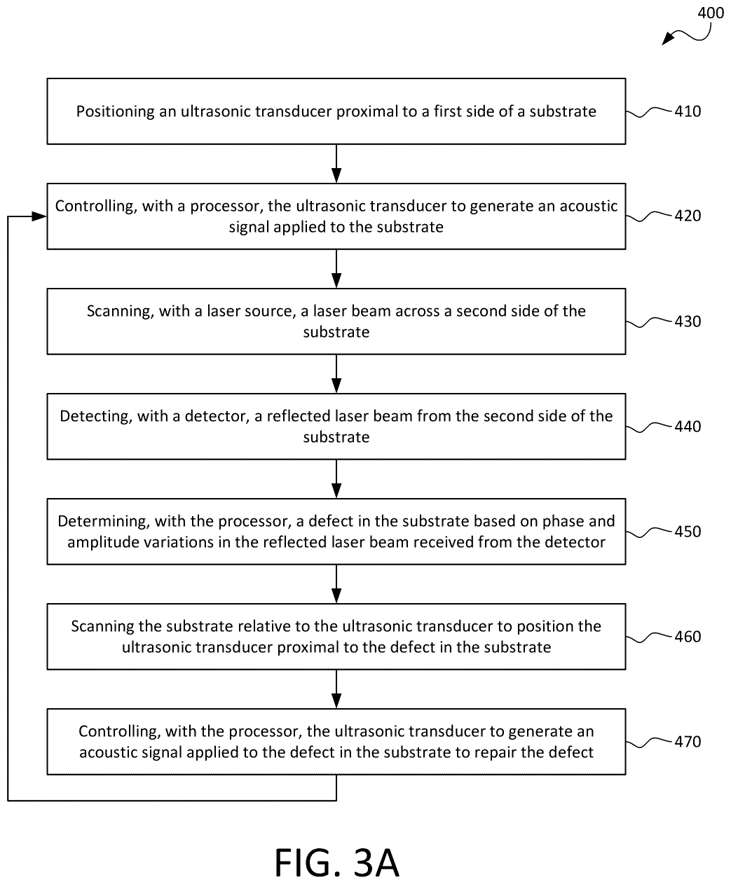

Another embodiment of the present disclosure provides a method 400, shown in FIG. 3A. A system 100b used in connection with the method 400 is shown in FIG. 3B. The system 100b differs from the system 100 in that instead of an ultrasonic detector 120, the system 100b includes a laser source 140 and a laser detector 145. The ultrasonic detector 120 is arranged proximal to a first side 101a of the substrate, while the laser source 140 is configured to emit laser light toward a second side 101b of the substrate 101, and the laser detector 145 is configured to detect laser light reflected by the second side 101b of the substrate 101. The laser source 140 may be a laser-diode (continuous wave or modulated) and the laser detector 145 may be a photodiode. In some embodiments, the laser detector 145 may be a pixelated detector. The method 400 may comprise the following steps.

At step 410, an ultrasonic transducer is positioned proximal to a first side of a substrate. In some embodiments, the substrate may comprise silicon, glass, ceramic, or organic materials. In other embodiments, the substrate may be a printed circuit board including a metal line (e.g., made of copper or other conductive materials).

At step 420, a processor controls the ultrasonic transducer to generate an acoustic signal applied to the substrate. The acoustic signal may have a frequency in the range of 10 s of MHz or up to several GHz. The acoustic signal generated by the ultrasonic transducer may be directed toward the first side of the substrate and may be reflected by the first side of the substrate.

At step 430, a laser source scans a laser beam across a second side of the substrate. The second side may be opposite to the first side. The laser beam may be a spot laser or a line. The scanning may be performed by moving the substrate, e.g., using a movable stage, scanning mirrors, or other means.

At step 440, a detector detects a reflected laser beam. The reflected laser beam may be a reflection of the laser beam from the second side of the substrate.

At step 450, the processor determines a defect in the substrate based on phase and amplitude variations in the reflected laser beam received from the detector. For example, a defect in the substrate may cause the amplitude of the reflected laser beam detected by the detector to be reduced and/or may cause a phase shift in the reflected laser beam detected by the detector. Thus, as the laser beam is scanned across the second side of the substrate, variations in the reflected laser beam can indicate defects, and the position of the defects can be identified based on the scan location.

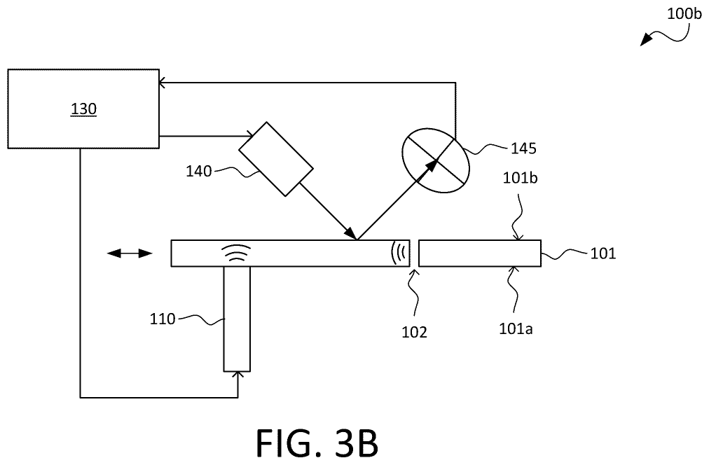

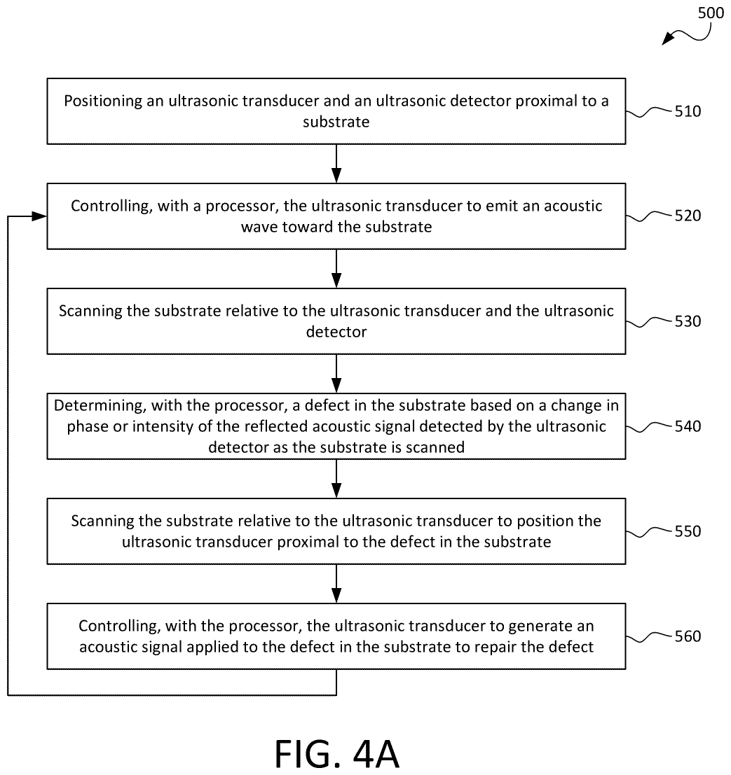

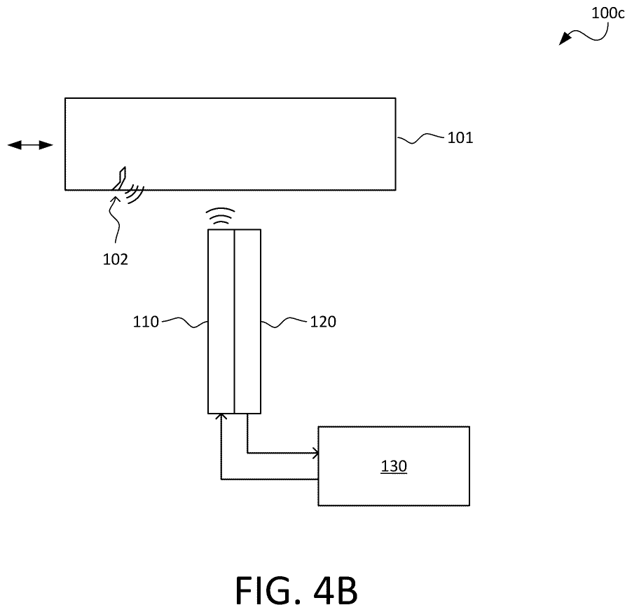

Another embodiment of the present disclosure provides a method 500, as shown in FIG. 4A. A system 100c used in connection with the method 500 is shown in FIG. 4B. The system 100c differs from the system 100 in that the substrate 101 is a solid-state battery, and the ultrasonic transducer 110 and the ultrasonic detector 120 are positioned proximal to the substrate 101, but not attached thereto. However, in some embodiments, the ultrasonic transducer 110 and the ultrasonic detector 120 may be indirectly attached to the substrate 101 by a mediator, such as a liquid, gel, or other material having an acoustic impedance similar to that of the substrate 101. The method 500 may comprise the following steps.

At step 510, an ultrasonic transducer and an ultrasonic detector are positioned proximal to a substrate. The ultrasonic transducer and the ultrasonic detector may be part of the same device. In some embodiments, the substrate may be a solid-state battery. In some embodiments the ultrasonic transducer may also function as an ultrasonic detector, based on careful time control between acoustic signal generation and detection.

At step 520, a processor controls the ultrasonic transducer to emit an acoustic wave toward the substrate. The acoustic signal may have a frequency in the range of 10 s of MHz or up to several GHz. The acoustic wave may be reflected by the substrate and received by the ultrasonic detector.

At step 530, the substrate is scanned relative to the ultrasonic transducer and the ultrasonic detector. For example, the substrate may be disposed on a stage that is movable relative to the ultrasonic transducer and the ultrasonic detector. Alternatively, the ultrasonic transducer and the ultrasonic detector may be movable relative to the substrate.

At step 540, the processor may determine a defect in the substrate based on a change in phase or intensity of the reflected acoustic signal detected by the ultrasonic detector as the substrate is scanned. For example, a defect in the substrate may cause the intensity of the reflected acoustic signal to be increased and/or change the phase of the reflected acoustic signal received by the ultrasonic detector due to a high impedance difference between the substrate and air. Thus, as the substrate is scanned relative to the ultrasonic transducer and the ultrasonic detector, variations in the reflected acoustic signal can indicate defects, and the position of the defects can be identified based on the scan location. In some embodiments, the defect may be a crack or dendrite in a solid-state battery.

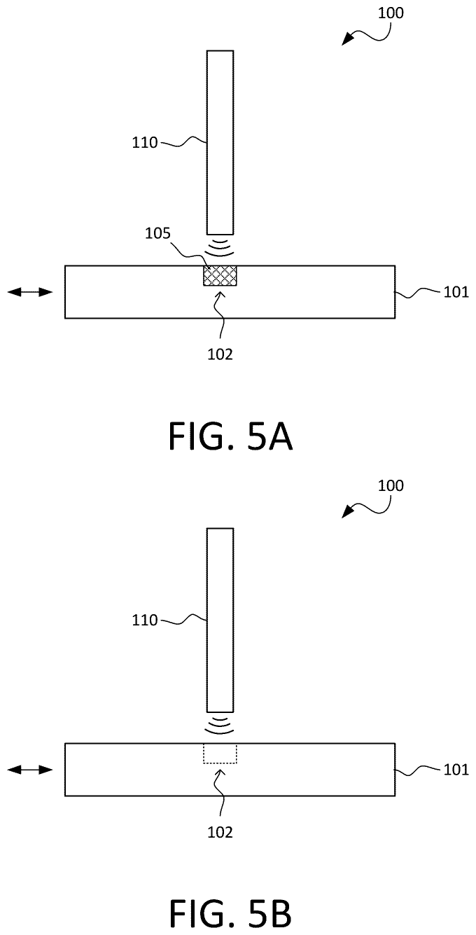

Following the methods 200, 300, 400, or 500 of the present disclosure, the defects detected can be repaired. For example, when additive processes are used to repair an open void or crack defect 102 in a substrate 101 (e.g., laser induced forward transfer (LIFT), inkjet, etc.), acoustic signals from an ultrasonic transducer 110 can be used to improve adhesion of the additive materials 105 to the substrate 101 or improve the material properties. As shown in FIGS. 5A and 5B, the ultrasonic transducer 110 can be positioned proximal to the additive materials 105, and the acoustic signal can be applied until the material in the defect 102 is uniform with the substrate 101.

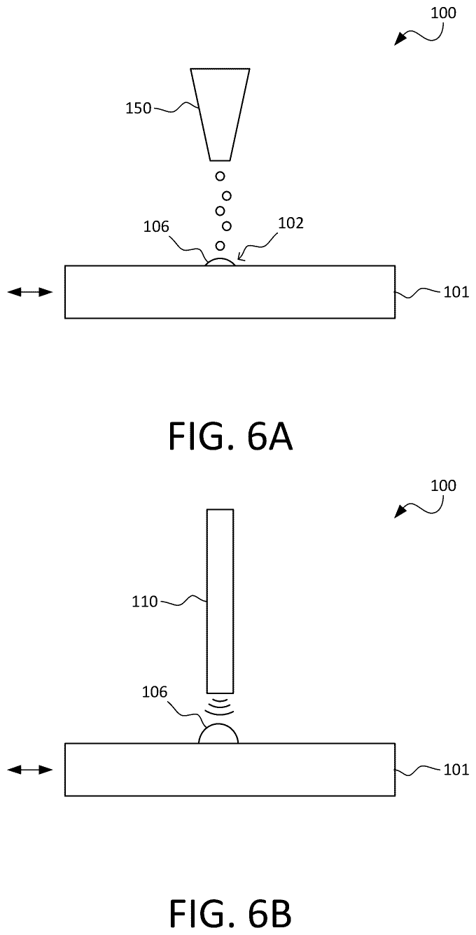

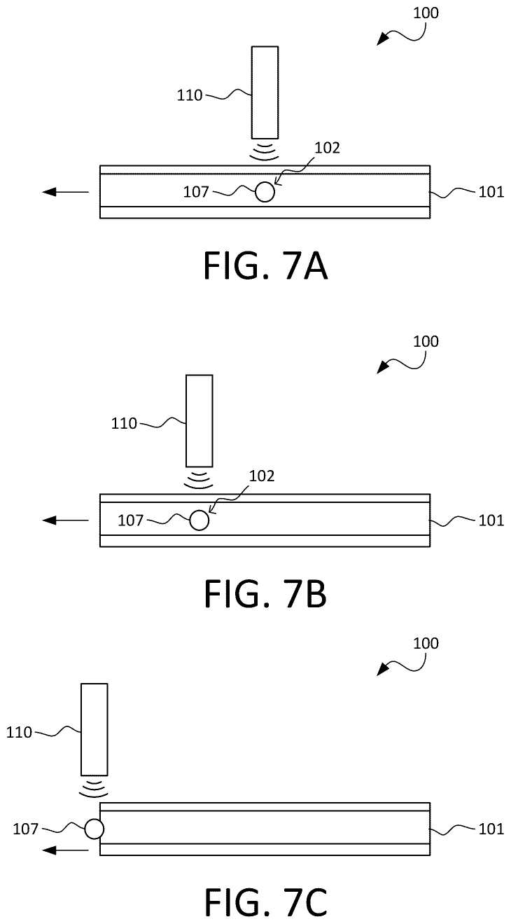

Alternatively, when solder bumps are added to correct defects in metals lines of a PCB, acoustic signals from an ultrasonic transducer can be used to melt or sinter the solder bump to reflow the solder material and repair a deformed or low solder bump. As shown in FIGS. 6A and 6B, solder material is deposited from a solder source 150 to form a solder bump 106. The solder bump may be a defect 102 when it is deformed or low. By applying the acoustic signal to the solder bump 106, the solder can be melted and reformed into a corrected form. In some embodiments, a void or defect 102 in the substrate 101 may be an air bubble 107 between layers of the substrate 101. As shown in FIGS. 7A to 7C, by applying acoustic signals from the ultrasonic transducer 110 to the substrate 101 and scanning the substrate 101 or the ultrasonic transducer 110, the air bubbles 107 can be pushed out of the substrate 101 to correct the defect 102. In any of the repair processes, the processor may use the location of the defect detected in the substrate to control the position where the acoustic signals are applied to the substrate to repair the defect, which can avoid damage to the substrate in locations where no defect is detected. The frequency of the acoustic signal generated by the ultrasonic transducer may be different in the repair process than the frequency used in the detection process. For example, the frequency of the acoustic signal generated by the ultrasonic transducer may be greater in the repair process than the frequency used in the detection process.

In an embodiment, the method 200 may further comprise step 260, shown in FIG. 1A. At step 260, the processor controls the ultrasonic transducer to generate an acoustic signal applied to the defect in the substrate to repair the defect. For example, the defect may be a void or crack in the substrate, and after filling the void or crack with additive material, the acoustic signal may improve adhesion or the material properties of the additive material, as shown in FIGS. 5A and 5B.

In another embodiment, the method 200 may further comprise step 270, as shown in FIG. 1A. At step 270, a solder material is deposited to the defect in the substrate to repair the defect. For example, the defect may be a crack in the metal line, and the solder material can be filled into the crack to repair the defect. In some embodiments, the defect in the substrate may be a void between repaired segments of the metal line, and solder material can be filled in the void to repair the defect. If the solder bump applied is deformed or low, the processor can further control the ultrasonic transducer to apply the acoustic signal to melt or sinter the solder bump, as shown in FIGS. 6A and 6B.

In some embodiments, after step 260 or step 270, steps 230 to 250 may be repeated to verify that no defects remain following the repair process or if further repair is needed.

In another embodiment, the method 300 may further comprise step 360, as shown in FIG. 2A. At step 360, the processor controls the multi-segment ultrasonic transducer to generate an acoustic signal from at least one segment applied to the defect in the underfill material to repair the defect. For example, the multi-segment ultrasonic transducer can generate an acoustic signal from at least one segment based on the location of the defect determined by the processor, and the acoustic signal applied to the defect may be configured to melt or sinter the underfill material to repair the defect. In some embodiments, after step 360, steps 330 to 350 may be repeated to verify that no defects remain following the repair process or if further repair is needed.

In another embodiment, the method 400 may further comprise steps 460 and 470, as shown in FIG. 3A. At step 460, the substrate is scanned relative to the ultrasonic transducer to position the ultrasonic transducer proximal to the defect in the substrate. The ultrasonic transducer may be positioned proximal to the defect in the substrate to avoid damaging areas of the substrate where there is not determined to be a defect. At step 470, the processor controls the ultrasonic transducer to generate an acoustic signal applied to the defect in the substrate to repair the defect. For example, the defect may be a void or crack in the substrate, and after filling the void or crack with additive material, the acoustic signal may improve adhesion or the material properties of the additive material, as shown in FIGS. 5A and 5B. In some embodiments, after step 470, steps 420 to 450 may be repeated to verify that no defects remain following the repair process or if further repair is needed.

In another embodiment, the method 500 may further comprise steps 550 and 560, as shown in FIG. 4A. At step 550, the substrate is scanned relative to the ultrasonic transducer to position the ultrasonic transducer proximal to the defect in the substrate. The ultrasonic transducer may be positioned proximal to the defect in the substrate to avoid damaging areas of the substrate where there is not determined to be a defect. At step 560, the processor controls the ultrasonic transducer to emit an acoustic wave applied to the defect in the substrate to repair the defect. For example, the defect may be a crack or dendrite in a solid-state battery, and after filling the crack or dendrite with an additive material, the acoustic wave may improve adhesion or the material properties of the additive material, as shown in FIGS. 5A and 5B. In some embodiments, after step 560, steps 520 to 540 may be repeated to verify that no defects remain following the repair process or if further repair is needed.

With the methods 200, 300, 400, and 500 of the present disclosure, defects in various types of substrates can be detected using ultrasound, and the defects can be repaired using ultrasound. Detection using ultrasound can be used for materials that may be opaque to optical detection. In addition, using ultrasound can improve detection resolution compared to other methods, based variability of the acoustic velocity and frequency of the applied acoustic signal. Accordingly, the detection methods can improve overall production yield.

Although the present disclosure has been described with respect to one or more particular embodiments, it will be understood that other embodiments of the present disclosure may be made without departing from the scope of the present disclosure. Hence, the present disclosure is deemed limited only by the appended claims and the reasonable interpretation thereof.

What is claimed is:

1. A method comprising:
attaching an ultrasonic transducer to a substrate;
attaching an ultrasonic detector to the substrate;
controlling, with a processor, the ultrasonic transducer to generate an acoustic signal applied to the substrate;
receiving, with the processor, a reflected acoustic signal detected by the ultrasonic detector; and
determining, with the processor, a defect in the substrate based on phase and intensity of the reflected acoustic signal compared to the acoustic signal applied to the substrate.

2. The method of claim 1, wherein the substrate comprises silicon, glass, ceramic, or organic materials, and the defect is a void or crack in the substrate.

3. The method of claim 1, wherein the substrate comprises a printed circuit board.

4. The method of claim 3, wherein the ultrasonic transducer is attached to a metal line of the printed circuit board and the ultrasonic detector is attached to the metal line, and the defect in the substrate is a crack in the metal line.

5. The method of claim 3, the ultrasonic transducer is attached to a metal line of the printed circuit board and the ultrasonic detector is attached to the metal line, and the defect in the substrate is a void between repaired segments of the metal line.

6. The method of claim 1, wherein the ultrasonic detector is attached to the substrate distal from the ultrasonic transducer.

7. The method of claim 1, wherein the ultrasonic detector is attached to the substrate at the same position as the ultrasonic transducer.

8. The method of claim 1, further comprising:
controlling, with the processor, the ultrasonic transducer to generate an acoustic signal applied to the defect in the substrate to repair the defect.

9. The method of claim 1, further comprising:
depositing solder material to the defect in the substrate to repair the defect.

10. A method comprising:
attaching a multi-segment ultrasonic transducer to a chip, wherein the chip is disposed on a substrate with underfill material disposed therebetween;
attaching an ultrasonic detector to the chip;
controlling, with a processor, the multi-segment ultrasonic transducer to generate an acoustic signal from each segment applied to the chip, wherein the acoustic signal from each segment of the multi-segment ultrasonic transducer has a phase delay;
receiving, with the processor, a reflected acoustic signal detected by the ultrasonic detector; and
determining, with the processor, a defect in the underfill material based on phase and intensity of the reflected acoustic signal.

11. The method of claim 10, wherein the phase delay of the acoustic signal from each segment of the multi-segment ultrasonic transducer focuses an acoustic wave at different depths relative to the chip, such that the acoustic wave is reflected by the underfill material and detected by the ultrasonic detector.

12. The method of claim 10, further comprising:
controlling, with the processor, the multi-segment ultrasonic transducer to generate an acoustic signal from at least one segment applied to the defect in the underfill material to repair the defect.

13. The method of claim 12, wherein the acoustic signal applied to the defect is configured to melt or sinter the underfill material to repair the defect.

14. A method comprising:
positioning an ultrasonic transducer proximal to a first side of a substrate;
controlling, with a processor, the ultrasonic transducer to generate an acoustic signal applied to the substrate;
scanning, with a laser source, a laser beam across a second side of the substrate, wherein the first side is opposite to the second side;
detecting, with a detector, a reflected laser beam, wherein the reflected laser beam is a reflection of the laser beam from the second side of the substrate; and
determining, with the processor, a defect in the substrate based on phase and amplitude variations in the reflected laser beam received from the detector.

15. The method of claim 14, further comprising:
controlling, with the processor, the ultrasonic transducer to generate an acoustic signal applied to the defect in the substrate to repair the defect.

16. The method of claim 15, wherein before controlling, with the processor, the ultrasonic transducer to generate an acoustic signal applied to the defect in the substrate to repair the defect, the method further comprises:
scanning the substrate relative to the ultrasonic transducer to position the ultrasonic transducer proximal to the defect in the substrate.

17. A method comprising:
positioning an ultrasonic transducer and an ultrasonic detector proximal to a substrate;
controlling, with a processor, the ultrasonic transducer to emit an acoustic wave toward the substrate, wherein the acoustic wave is reflected by the substrate and received by the ultrasonic detector;
scanning the substrate relative to the ultrasonic transducer and the ultrasonic detector; and
determining, with the processor, a defect in the substrate based on a change in phase or intensity of the reflected acoustic wave detected by the ultrasonic detector as the substrate is scanned.

18. The method of claim 17, wherein the substrate is a solid-state battery, and the defect is a crack or dendrite in the solid-state battery.

19. The method of claim 17, further comprising:
controlling, with the processor, the ultrasonic transducer to emit an acoustic wave applied to the defect in the substrate to repair the defect.

20. The method of claim 19, wherein before controlling, with the processor, the ultrasonic transducer to emit an acoustic wave applied to the defect in the substrate to repair the defect, the method further comprises:
scanning the substrate relative to the ultrasonic transducer to position the ultrasonic transducer proximal to the defect in the substrate.
